(19) United States
(12) Patent Application Publication
(10) Pub. No.: US 2019/0385834 A1
(43) Pub. Date: Dec. 19, 2019

(54) SUBSTRATE PROCESSING METHOD

(71) Applicant: EBARA CORPORATION, Tokyo (JP)

(72) Inventors: Masayuki Nakanishi, Tokyo (JP); Satoru Yamamoto, Toyko (JP); Kenji Kodera, Tokyo (JP)

(21) Appl. No.: 16/432,315

(22) Filed: Jun. 5, 2019

(30) Foreign Application Priority Data
Jun. 14, 2018 (JP) 2018-113344

(51) Int. Cl. H01L 21/02; B24B 9/06; H01L 21/304

(52) U.S. Cl. CPC H01L 21/02041; H01L 21/304; H01L 21/02021; B24B 9/065

(57) ABSTRACT

A substrate processing method capable of preventing an adherence of a foreign matter to a substrate is disclosed. The substrate processing method comprises: a substrate rotating step of rotating a substrate W while holding the substrate W; a first-liquid upper supply step of supplying a first liquid onto an upper surface of the substrate W while rotating the substrate W; a polishing step of pressing a polishing tape 23 to the substrate W while supplying the first liquid in a state of rotating the substrate W; a second-liquid upper supply step of supplying a second liquid onto the upper surface of the substrate W while rotating the substrate W; and a cleaning step of pressing a cleaning tape 29 to the substrate W while supplying the second liquid in a state of rotating the substrate W and terminating after the polishing step is terminated. The second liquid is either of a conducting water, a surfactant solution, or ozone water.

### CROSS REFERENCE TO RELATED APPLICATION

This document claims priority to Japanese Patent Application Number 2018-113344 filed Jun. 14, 2018, the entire contents of which are hereby incorporated by reference.

### BACKGROUND

Semiconductor devices are formed on a surface (i.e., device surface) of a wafer. When a foreign matter (particles) such as polishing debris adheres to the wafer, the foreign matter contaminates the wafer. As a result, a yield in a semiconductor manufacturing is lowered. Therefore, from a viewpoint of improving the yield, management of surface conditions of the wafer with respect to the foreign matter is important.

There is a method for transporting the wafer by holding only a peripheral portion of the wafer with an arm. In such a method, an unnecessary film remaining on the peripheral portion of the wafer may be peeled off and adhere to the surface of the wafer while passing through various processes. As a result, the yield is lowered. Therefore, from the viewpoint of improving the yield, it is important to remove the unnecessary film formed on the peripheral portion of the wafer. Therefore, a substrate processing apparatus may include a bevel polishing apparatus configured to polish the peripheral portion of the wafer to remove the unnecessary film.

When the foreign matter adheres to a back surface (i.e., a surface opposite to a front surface) of the wafer, the wafer can separate from a stage reference surface or the front surface of the wafer can become inclined with respect to the stage reference surface in an exposure apparatus, resulting in patterning deviation or deviation of focal distance. As a result, the yield is lowered. Therefore, from the viewpoint of improving yield, it is important to remove the foreign matter adhering to the back surface of the wafer. Therefore, the substrate processing apparatus may include a back surface polishing apparatus configured to remove the foreign matter adhering to the back surface of the wafer.

In recent years, miniaturization of the semiconductor devices formed on the surface of the wafer has progressed. With the miniaturization of the semiconductor devices, it is required to yearly improve the performance (i.e., particle performance) with respect to an adherence of the foreign matter to the wafer. In order to improve the particle performance, it is conceivable to improve a cleaning capacity of the substrate processing apparatus. However, if the adherence of the foreign matter to the wafer can be prevented, the particle performance in the entire apparatus is improved, and cleaning of the wafer as a later process becomes easy.

### SUMMARY OF THE INVENTION

According to an embodiment, there is provided a substrate processing method capable of preventing an adherence of a foreign matter to a wafer (substrate).

Embodiments, which will be described below, relate to a substrate processing method for processing a surface of a substrate such as a wafer.

In an embodiment, there is provided a method comprising: a substrate rotating step of rotating a substrate while holding the substrate; a first-liquid upper supply step of supplying a first liquid onto an upper surface of the substrate while rotating the substrate; a polishing step of pressing a polishing tape to the substrate while supplying the first liquid in a state of rotating the substrate; a second-liquid upper supply step of supplying a second liquid onto the upper surface of the substrate while rotating the substrate, the second liquid being either of a conducting water, a surfactant solution, or ozone water; and a cleaning step of pressing a cleaning tape to the substrate while supplying the second liquid in a state of rotating the substrate and terminating after the polishing step is terminated.

In an embodiment, the first liquid is either of pure water, a conducting water, a surfactant solution, or ozone water.

In an embodiment, the method further comprises a third-liquid upper supply step of supplying a third liquid being either of pure water or a conducting water onto the upper surface of the substrate while rotating the substrate after the second liquid upper supply step is terminated.

In an embodiment, the polishing step comprises a pressing of the polishing tape to a peripheral portion of the substrate; and the cleaning step comprises a pressing of the cleaning tape to the peripheral portion of the substrate.

In an embodiment, the upper surface of the substrate is a back surface with no device is formed; the polishing step comprises a pressing of the polishing tape to the back surface of the substrate; and the cleaning step comprises a pressing of the cleaning tape to the back surface of the substrate.

In an embodiment, the polishing tape is a tape having a first abrasive grain on a surface of the polishing tape; and the cleaning tape is a tape having no abrasive grain on a surface of the cleaning tape or having a second abrasive grain.

In an embodiment, the first abrasive grain is a diamond abrasive grain; and the second abrasive grain is a silica abrasive grain.

In an embodiment, a particle size of the second abrasive grain is smaller than a particle size of the first abrasive grain.

In an embodiment, the substrate rotating step, the first-liquid upper supply step, the polishing step, the second-liquid upper supply step, and the cleaning step are performed in a state of eliminating a static electricity from the substrate.

In an embodiment, the method further comprises a first-liquid lower supply step of supplying a liquid of the same type as the first liquid onto a lower surface of the substrate in the first-liquid upper supply step; and a second-liquid lower supply step of supplying a liquid of the same type as the second liquid onto the lower surface of the substrate in the second-liquid upper supply step.

In the second-liquid upper supply step, the second liquid capable of effectively preventing an adherence of the foreign matter to the substrate is supplied onto the substrate, and the cleaning tape is pressed against the substrate while supplying the second liquid. Therefore, the adherence of the foreign matter generated in the polishing step to the substrate can be reliably prevented.

### BRIEF DESCRIPTION OF THE DRAWINGS

FIGS. 1A and 1B are enlarged cross-sectional views each showing a peripheral portion of a wafer which is an example of a substrate;

FIG. 2 is a view showing an embodiment of a polishing apparatus;

FIG. 3 is an enlarged view of a polishing head;

FIG. 4 is a view showing the manner in which the polishing head polishes a bevel portion of the wafer;

FIG. 5 is a view showing liquids supplied from an upper liquid supply device and lower liquid supply devices toward the wafer;

FIG. 6 is a flow chart showing an embodiment of a substrate processing method performed by the polishing apparatus;

FIG. 7 is a view showing a sequence of the substrate processing method according to an embodiment;

FIG. 8 is a view showing the polishing apparatus during a polishing step;

FIG. 9 is a view showing the polishing apparatus during a cleaning step;

FIG. 10 is a view showing a temporal variation of an amount of static electricity of the wafer;

FIG. 11 is a view showing a sequence of the substrate processing method according to another embodiment;

FIG. 12 is a view showing a sequence of the substrate processing method according to still another embodiment;

FIG. 13 is a plan view of a substrate processing apparatus including a plurality of polishing apparatuses described above;

FIG. 14 is a schematic view showing another embodiment of the polishing apparatus;

FIG. 15 is a view showing an example of an interior structure of a processing head;

FIG. 16 is a view of the processing head as seen from below;

FIG. 17 is a schematic view showing one of a plurality of processing cartridges;

and

FIG. 18 is a schematic view showing a state in which a pressing member and a scrubbing tape are located at a retreat position.

### DESCRIPTION OF EMBODIMENTS

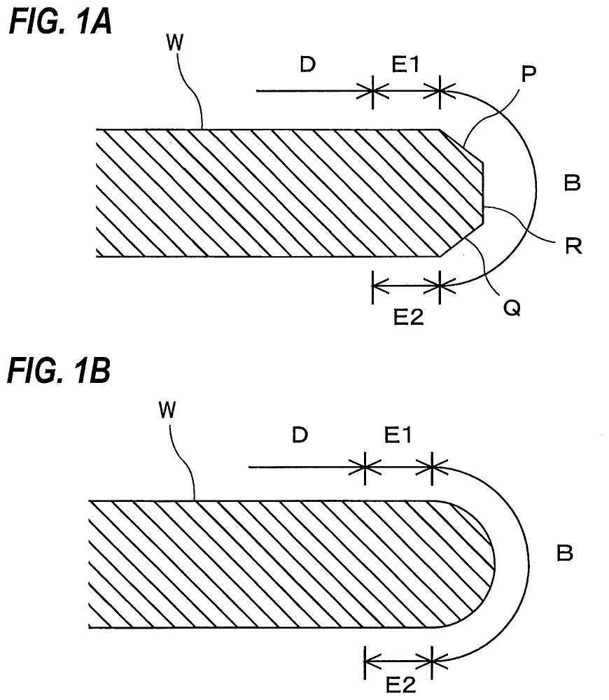

Embodiments will now be described with reference to the drawings. FIGS. 1A and 1B are enlarged cross-sectional views each showing a peripheral portion of a wafer which is an example of a substrate. More specifically, FIG. 1A is a cross sectional view of a wafer of a so-called straight type, and FIG. 1B is a cross sectional view of a wafer of a so-called round type. In a wafer W shown in FIG. 1A, a bevel portion is an outermost circumferential surface (indicated by symbol B) including an upper slope (or an upper bevel portion) P, a lower slope (or a lower bevel portion) Q, and a side portion (or an apex) R of the wafer W.

In a wafer W shown in FIG. 1B, a bevel portion is a portion B constituting an outermost circumferential surface of the wafer W and having a curved cross section. The top edge portion is a flat portion E1 located radially inwardly of the bevel portion B and located radially outwardly of a region D where devices are formed. A bottom edge portion is a flat portion E2 located radially inwardly of the bevel portion B and located at an opposite side from the top edge portion. The top edge portion E1 and the bottom edge portion E2 may be collectively referred to as a near edge portion.

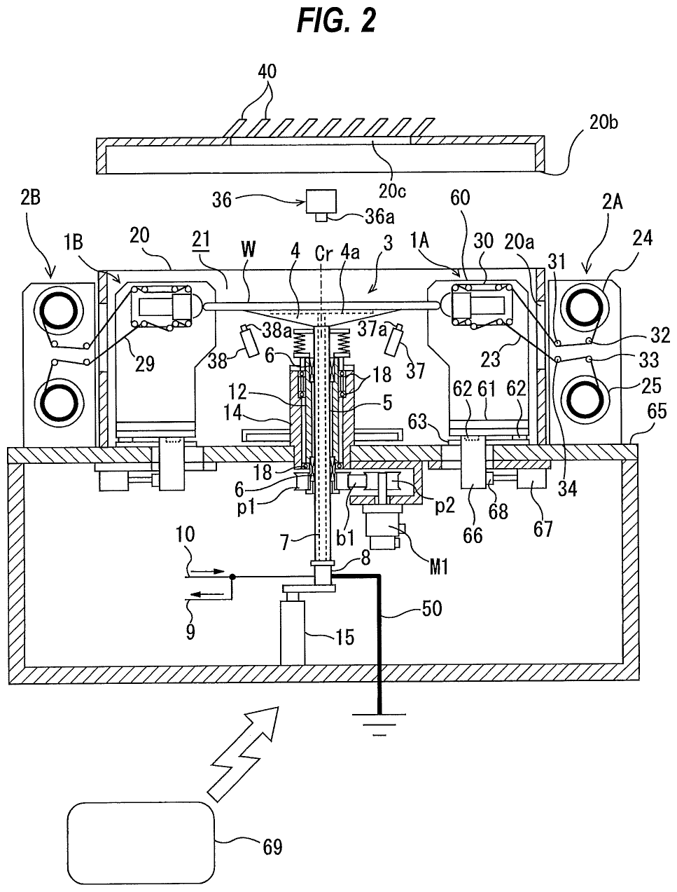

FIG. 2 is a view showing an embodiment of a polishing apparatus. In the embodiment shown in FIG. 2, the polishing apparatus is a bevel polishing apparatus configured to polish the peripheral portion of the wafer W. As shown in FIG. 2, the polishing apparatus includes a rotary holding mechanism 3 configured to hold a wafer W horizontally and to rotate the wafer W. The rotary holding mechanism 3 is located in the center of the polishing apparatus. FIG. 2 shows a state in which the rotary holding mechanism 3 holds the wafer W. This rotary holding mechanism 3 has a dish-shaped holding stage 4 configured to hold a back surface of the wafer W by a vacuum suction, a hollow shaft 5 coupled to a central portion of the holding stage 4, and a motor M1 for rotating the hollow shaft 5. The wafer W is placed onto the holding stage 4 by hands of a transporting mechanism (not shown) such that a center of the wafer W is aligned with a central axis of the hollow shaft 5.

The hollow shaft 5 is supported by ball spline bearings (i.e., linear motion bearings) 6 which allow the hollow shaft 5 to move vertically. The holding stage 4 has an upper surface having grooves 4a. These grooves 4a communicate with a communication line 7 extending through the hollow shaft 5. The communication line 7 is coupled to a vacuum line 9 via a rotary joint 8 provided on a lower end of the hollow shaft 5.

The communication line 7 is also coupled to a nitrogen-gas supply line 10 for use in releasing the wafer W from the holding stage 4 after processing. By selectively coupling the vacuum line 9 and the nitrogen-gas supply line 10 to the communication line 7, the wafer W can be held on the upper surface of the holding stage 4 by the vacuum suction and can be released from the upper surface of the holding stage 4.

A pulley p1 is coupled to the hollow shaft 5, and a pulley p2 is mounted on a rotational shaft of the motor M1. The hollow shaft 5 is rotated by the motor M1 through the pulley p1, the pulley p2, and a belt b1 riding on these pulleys p1 and p2. With these structures, the wafer W, held on the upper surface of the holding stage 4, is rotated by the motor M1.

The ball spline bearing 6 is a bearing that allows the hollow shaft 5 to move freely in its longitudinal direction. The ball spline bearings 6 are secured to a cylindrical casing 12. Therefore, in the resent embodiment, the hollow shaft 5 can move linearly up and down relative to the casing 12, and the hollow shaft 5 and the casing 12 rotate in unison. The hollow shaft 5 is coupled to an air cylinder (elevating mechanism) 15, so that the hollow shaft 5 and the holding stage 4 are elevated and lowered by the air cylinder 15.

A cylindrical casing 14 is provided so as to surround the casing 12 in a coaxial arrangement. Radial bearings 18 are provided between the casing 12 and the cylindrical casing 14, so that the casing 12 is rotatably supported by the radial bearings 18. With these structures, the rotary holding mechanism 3 can rotate the wafer W about its central axis Cr and can elevate and lower the wafer W along the central axis Cr.

A plurality of (in this embodiment, two) polishing head assemblies 1A and 1B are arranged around the wafer W held by the rotary holding mechanism 3. Tape supply and recovery mechanisms 2A and 2B are provided radially outwardly of the polishing head assemblies 1A and 1B, respectively. The polishing head assemblies 1A and 1B are isolated from the tape supply and recovery mechanisms 2A and 2B by a partition 20.

An interior space of the partition 20 provides a polishing room 21. The two polishing head assemblies 1A, 1B and the holding stage 4 are located in the polishing room 21. On the other hand, the tape supply and recovery mechanisms 2A and 2B are located outside the partition 20 (i.e., outside the polishing room 21). An upper surface of the partition 20 has an aperture 20c and louvers 40.

During a polishing process, an entrance 20b is closed by a non-illustrated shutter. Therefore, as a fan mechanism (not shown) is driven to evacuate an air, downward flow of clean air is foamed in the polishing room 21. Because the polishing process is performed under such conditions, the polishing liquid is prevented from scattering upwardly. Therefore, the polishing process can be performed while an upper space of the polishing room 21 is kept clean.

The polishing head assemblies 1A and 1B have the same structure, and the tape supply and recovery mechanisms 2A and 2B also have the same structure. Although two polishing head assemblies and two tape supply and recovery mechanism are provided in this embodiment, the number of polishing head assemblies and the number of tape supply and recovery mechanisms are not limited to this embodiment.

The polishing head assembly 1A and the tape supply and recovery mechanism 2A will be described below. The tape supply and recovery mechanism 2A includes a supply reel 24 for supplying a polishing tape 23 as an example of a polishing tool to the polishing head assembly 1A, and a recovery reel 25 for recovering the polishing tape 23 that has been used in polishing of the wafer W. The supply reel 24 is arranged above the recovery reel 25.

The polishing tape 23 is a long tape-shaped polishing tool, and one of surfaces of the polishing tape 23 provides a polishing surface. The polishing tape 23 is mounted on the tape supply and recovery mechanism 2A in a state where the polishing tape 23 is wound on the supply reel 24. One end of the polishing tape 23 is attached to the recovery reel 25. The recovery reel 25 takes up the polishing tape 23 that has been supplied to the polishing head assembly 1A to thereby recover the polishing tape 23. The polishing head assembly 1A has a polishing head 30 for pressing the polishing tape 23, supplied from the polishing-tape supply mechanism 2A, against the peripheral portion of the wafer W. The polishing tape 23 is supplied to the polishing head 30 such that the polishing surface of the polishing tape 23 faces the wafer W.

The tape supply and recovery mechanism 2A has plural guide rollers 31, 32, 33, and 34. The polishing tape 23, to be supplied to and recovered from the polishing head assembly 1A, is guided by these guide rollers 31, 32, 33, and 34. The polishing tape 23 is supplied to the polishing head 30 from the supply reel 24 through an opening 20a formed in the partition 20, and the polishing tape 23 that has been used is recovered by the recovery reel 25 through the opening 20a.

The polishing apparatus includes an upper liquid supply device 36 disposed above an upper surface of the wafer W, and lower liquid supply devices 37 and 38 disposed below a lower surface of the wafer W. The upper liquid supply device 36 supplies the liquid toward the center of the upper surface of the wafer W held by the rotary holding mechanism 3. Each of the lower liquid supply devices 37 and 38 supplies the liquid toward a boundary (in this embodiment, an outer peripheral portion of the holding stage 4) between the lower surface of the wafer W (in this embodiment, the back surface of the wafer W) and the holding stage 4. The configurations of the upper liquid supply device 36 and the lower liquid supply devices 37 and 38 will be described later.

The polishing apparatus includes a tilting mechanism 60 configured to tilt the polishing head 30. The tilting mechanism 60 includes a motor (not shown) coupled to the polishing head 30. When the motor rotates in a clockwise direction and a counterclockwise direction through a certain angle, the polishing head 30 rotates about an axis perpendicular to the central axis Cr through a certain angle.

As shown in FIG. 2, the tilting mechanism 60 is mounted on a plate-shaped movable base 61. This movable base 61 is movably coupled to a base plate 65 via guides 62 and rails 63. The rails 63 extend linearly in a radial direction of the wafer W held on the rotary holding mechanism 3, so that the movable base 61 can move linearly in the radial direction of the wafer W. A connection plate 66, extending through the base plate 65, is secured to the movable base 61. A linear actuator 67 is coupled to the connection plate 66 via a joint 68. This linear actuator 67 is secured to the base plate 65 directly or indirectly.

The linear actuator 67 may comprise an air cylinder or a combination of a positioning motor and a ball screw. The linear actuator 67, the rails 63, and the guides 62 constitute a moving mechanism for linearly moving the polishing head 30 in the radial direction of the wafer W. Specifically, the moving mechanism is operable to move the polishing head 30 closer to and away from the wafer W along the rails 63. On the other hand, the tape supply and recovery mechanism 2A is fixed to the base plate 65.

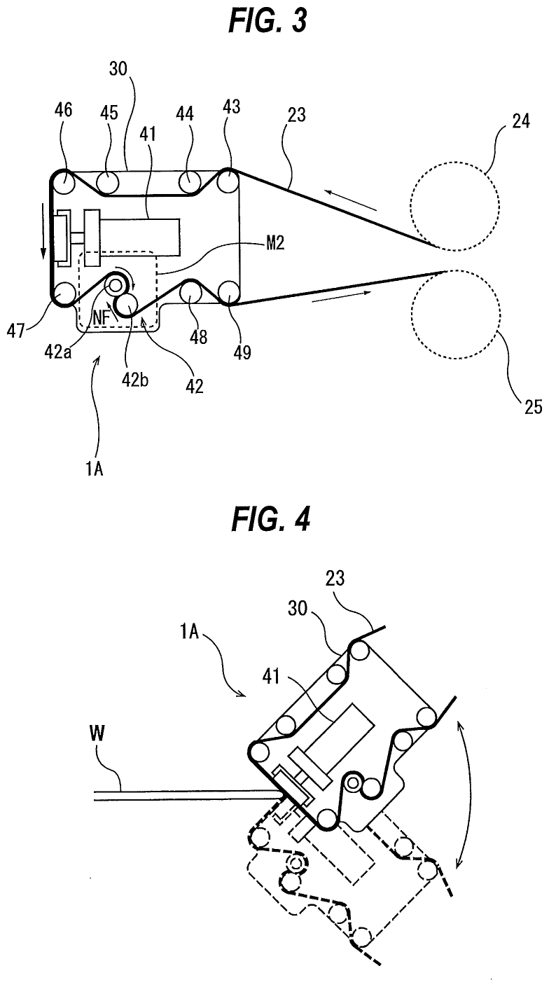

FIG. 3 is an enlarged view of the polishing head 30. As shown in FIG. 3, the polishing head 30 includes a pressing mechanism 41 configured to press the back surface of the polishing tape 23 to thereby press the polishing surface of the polishing tape 23 against the wafer W at a predetermined force. The polishing head 30 further includes a tape feed mechanism 42 configured to feed the polishing tape 23 from the supply reel 24 to the recovery reel 25. The polishing head 30 has plural guide rollers 43, 44, 45, 46, 47, 48, and 49, which guide the polishing tape 23 such that the polishing tape 23 travels in a direction perpendicular to the tangential direction of the wafer W.

The tape feed mechanism 42 provided in the polishing head 30 includes a tape feed roller 42a, a tape-holding roller 42b, and a motor M2 configured to rotate the tape feed roller 42a. The motor M2 is mounted on a side surface of the polishing head 30. The tape feed roller 42a is connected to a rotational shaft of the motor M2. The tape-holding roller 42b is provided adjacent to the tape feed roller 42a. The polishing tape 23 is wound about half around the tape feed roller 42a. The tape-holding roller 42b is supported by a non-illustrated mechanism, which biases the tape-holding roller 42b in a direction indicated by arrow NF in FIG. 3 (i.e., in a direction toward the tape feed roller 42a) so as to press the tape-holding roller 42b against the tape feed roller 42a.

FIG. 4 is a view showing the manner in which the polishing head 30 polishes the bevel portion of the wafer W. When polishing the peripheral portion of the wafer W, as shown in FIG. 4, the polishing tape 23 is pressed against the peripheral portion (e.g., the bevel portion) of the wafer W by the pressing mechanism 41 while the inclination angle of the polishing head 30 is changed continuously by the tilting mechanism 60. During polishing of the wafer W, the polishing tape 23 may be fed at a predetermined speed by the tape feed mechanisms 42.

In this embodiment, as shown in FIG. 2, the polishing tape 23 is set in the polishing head assembly 1A. A cleaning tape 29 different from the polishing tape 23 is set in a polishing head assembly 1B. The cleaning tape 29 is a long tape-shaped cleaning tool for removing fine foreign matters generated by polishing. The cleaning tape 29 is pressed against the peripheral portion (e.g., bevel portion) by the pressing mechanism 41 of the polishing head 30 of the polishing head assembly 1B.

The polishing tape 23 is a tape having a first abrasive grain on a surface of the polishing tape 23. The cleaning tape 29 is a tape having no abrasive grain on a surface of the cleaning tape 29 or having a second abrasive grain different from the first abrasive grain. In one embodiment, when the cleaning tape 29 is a tape having no abrasive grain, the cleaning tape 29 may be composed of non-woven fabric, polyurethane, or polyethylene.

In one embodiment, when the polishing tape 23 has a diamond abrasive grain as the first abrasive grain and the cleaning tape 29 is a tape having the second abrasive grain, the cleaning tape 29 may have a silica abrasive grain as the second abrasive grain. In another embodiment, a particle size of the second abrasive grain of the cleaning tape 29 may be smaller than a particle size of the first abrasive grain of the polishing tape 23.

As shown in FIG. 2, the polishing apparatus includes an operation controller 69 configured to control an operation of a component of the polishing apparatus. The operation controller 69 controls the operations of the components including the tilting mechanisms 60, the pressing mechanism 41, and the tape feed mechanism 42 of two polishing head assemblies 1A, 1B disposed around the wafer W, a moving mechanism for moving each polishing head assembly, the upper liquid supply device 36, and the lower liquid supply devices 37, 38.

The configurations of the upper liquid supply device 36 and the lower liquid supply devices 37, 38 will be described with reference to FIG. 2. The upper liquid supply device 36 is configured to selectively supply a plurality of types of liquids including at least pure water (DIW), a conducting water (e.g., a carbonated water (CO₂ water)), a surfactant solution (e.g., a solution in which a surfactant such as a chelating agent is dissolved), and ozone water (O₃ water) onto the upper surface of the wafer W. In this embodiment, the upper liquid supply device 36 is configured to supply the liquid selected from pure water, the conducting water, the surfactant solution, and ozone water onto the upper surface of the wafer W according to a process of the wafer W.

The structure of the upper liquid supply device 36 is not particularly limited as long as the upper liquid supply device 36 can selectively supply a plurality of types of liquids. In one embodiment, the upper liquid supply device 36 may include liquid supply lines (not shown). The number of liquid supply lines corresponds to that of the type of liquid that can be supplied. The liquid supply lines are coupled to a single supply nozzle 36a disposed so as to face the upper surface of the wafer W. An on-off valve is attached to each liquid supply line. The upper liquid supply device 36 having such configuration can selectively supply the liquid to be supplied from the supply nozzle 36a. In another embodiment, the upper liquid supply device 36 may include supply nozzles. The number of supply nozzles corresponds to that of the type of liquid that can be supplied. In this case, each supply nozzle is connected to the above-described each liquid supply line.

The lower liquid supply devices 37, 38 have the same configuration as the upper liquid supply device 36. Each of the lower liquid supply deices 37, 38 is configured to selectively supply a plurality of types of liquids including at least pure water (DIW), a conducting water (e.g., a carbonated water (CO₂ water)), a surfactant solution, and ozone water (O₃ water) onto the back surface of the wafer W. A supply nozzle 37a of the lower liquid supply device 37 and a supply nozzle 38a of the lower liquid supply device 38 are disposed so as to face the boundary between the lower surface of the wafer W and the holding stage 4. In this embodiment, each of lower liquid supply devices 37, 38 is configured to supply the liquid selected from pure water, the conducting water, the surfactant solution, and ozone water onto the lower surface of the wafer W according to the process of the wafer W.

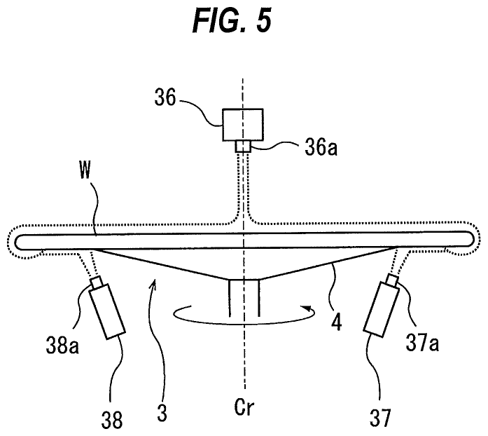

FIG. 5 is a view showing the liquids supplied from the upper liquid supply device 36 and the lower liquid supply devices 37, 38 toward the wafer W. In FIG. 5, the components of the polishing apparatus are schematically illustrated, and the liquids supplied onto the wafer W are illustrated by dotted lines.

As shown in FIG. 5, the wafer W rotates about the central axis Cr by the rotary holding mechanism 3. The upper liquid supply device 36 supplies the liquid toward the upper surface of the wafer W in a laminar flow. The liquid supplied onto the upper surface of the wafer W moves on the upper surface of the wafer W from the center of the wafer W toward radially outwardly of the wafer W by a centrifugal force. The liquid moves on the bevel portion of the wafer W and eventually moves to the lower surface of the wafer W (in this embodiment, the bottom edge portion E2 (see FIG. 1)). In this manner, the liquid supplied from the upper liquid supply device 36 covers not only the entire upper surface of the wafer W but also the bottom edge portion E2 of the wafer W.

The liquids supplied from the lower liquid supply devices 37, 38 onto the lower surface of the wafer W move on the lower surface of the wafer W from the boundary between the lower surface of the wafer W and the holding stage 4 toward the bevel portion of the wafer W by the centrifugal force, and the liquids contact the liquid supplied from the upper liquid supply device 36. As a result, the liquid supplied from the upper liquid supply device 36 and the liquids supplied from the lower liquid supply devices 37, 38 cover the entire surface of the wafer W excluding a holding surface of the wafer W held by the holding stage 4.

The operation controller 69 independently controls liquid supply operations of the upper liquid supply device 36 and the lower liquid supply devices 37, 38. More specifically, the operation controller 69 can select the liquid to be supplied from the upper liquid supply device 36 from a plurality of types of liquids and can determine a timing of supplying the liquid. Similarly, the operation controller 69 can select the liquid to be supplied from each of the lower liquid supply devices 37, 38 from a plurality of types of liquids and can determine the timing of supplying the liquid.

A substrate processing method capable of removing an unnecessary film remaining on the bevel portion of the wafer W by polishing and reliably preventing the adherence of the foreign matter generated by polishing to the wafer W will be described. The substrate processing method can reliably prevent a contamination of the wafer W. As a result, the reliability and the yield of the polishing apparatus can be improved.

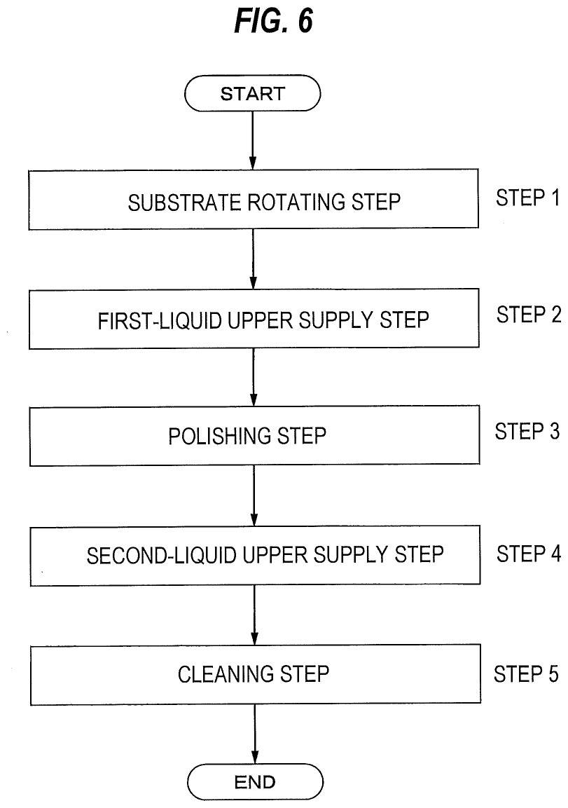

FIG. 6 is a flow chart showing an embodiment of the substrate processing method performed by the polishing apparatus. As shown in FIG. 6, the operation controller 69 of the polishing apparatus perfoi us a substrate rotating step (see step 1 in FIG. 6) of rotating the wafer W while holding the wafer W by the rotary holding mechanism 3, a first-liquid upper supply step (see step 2 in FIG. 6) of supplying a first liquid onto the upper surface of the wafer W by the upper liquid supply device 36 while rotating the wafer W, a polishing step (see step 3 in FIG. 6) of pressing the polishing tape 23 against the wafer W by the polishing head 30 while supplying the first liquid in a state of rotating the wafer W, a second-liquid upper supply step (see step 4 in FIG. 6) of supplying a second liquid onto the upper surface of the wafer W by the upper liquid supply device 36 while rotating the wafer W, and a cleaning step (see step 5 in FIG. 6) of pressing the cleaning tape 29 against the wafer W by the polishing head 30 while supplying the second liquid in a state of rotating the wafer W and teuninating after terminating of the polishing step.

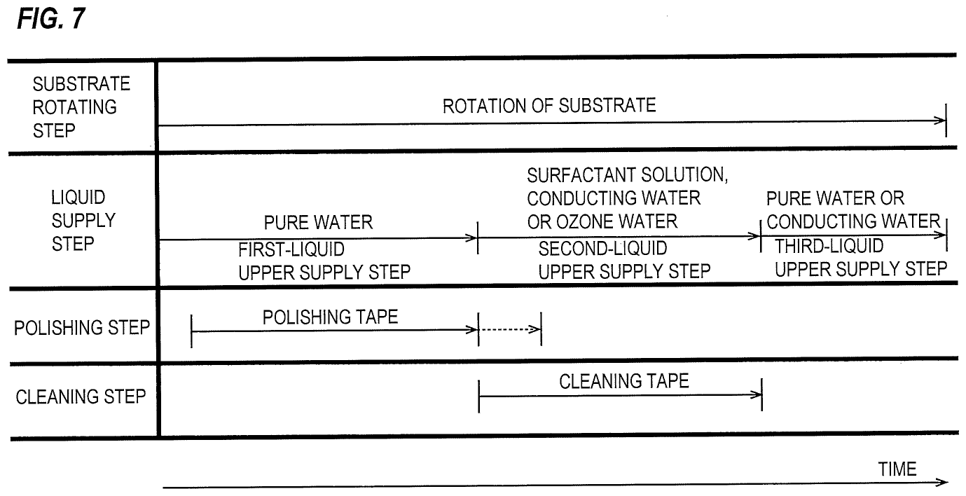

FIG. 7 is a view showing a sequence of the substrate processing method according to an embodiment. First, when the wafer W is transferred to a predetermined position above the holding stage 4, the holding stage 4 is elevated, and the wafer W is held by the upper surface of the holding stage 4 via vacuum suction. Thereafter, the holding stage 4 holding the wafer W is lowered to a predetermined polishing position, and the rotating holding mechanism 3 rotates the wafer W together with the holding stage 4. The upper liquid supply device 36 supplies the first liquid onto the upper surface of the wafer W with the rotation of the wafer W (first-liquid upper supply step).

The first liquid is either of pure water, the conducting water, the surfactant solution, or ozone water. The polishing apparatus may perform a step (first-liquid lower supply step) for supplying a liquid of the same type as the first liquid from the lower liquid supply devices 37, 38 onto the lower surface of the wafer W during the first liquid upper supply step. In the embodiment shown in FIG. 7, the first liquid is pure water. In this manner, the entire surface of the wafer W is covered with the liquid. In one embodiment, a flow rate of the liquid supplied from each of the lower liquid supply devices 37, 38 is smaller than the flow rate of the liquid supplied from the upper liquid supply device 36.

In the embodiment shown in FIG. 7, the first-liquid upper supply step and the substrate rotating step are started at the same time. In one embodiment, the substrate rotating step may be started after the first-liquid upper supply step is started. In another embodiment, the first-liquid upper supply step may be started after the substrate rotating step is started. The polishing step is started after the wafer W is covered with the first liquid by the first-liquid upper supply step (and the first-liquid lower supply step).

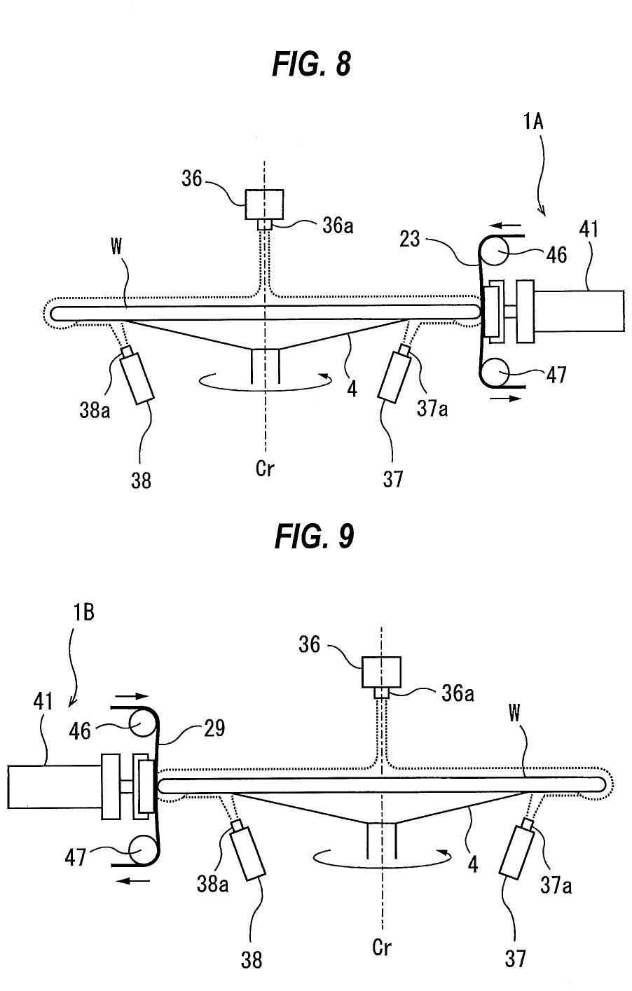

FIG. 8 is a view showing the polishing apparatus during the polishing step. As shown in FIG. 8, the first liquid covering the wafer W moves radially outwardly of the wafer W with the foreign matter while preventing the adherence of the foreign matter (particle) generated by polishing of the wafer W to the surface of the wafer W. The first liquid cools and lubricates a contact portion between the bevel portion of the wafer W and the polishing tape 23, and further removes the foreign matter from the wafer W as the polishing tape 23 advances. The liquid supplied in the first-liquid lower supply step can prevent the adherence of the foreign matter to the lower surface of the wafer W and can prevent a formation of a watermark on the lower surface of the wafer W by covering the lower surface of the wafer W with the liquid.

As shown in FIG. 7, the substrate rotating step and the first-liquid upper supply step are continued while performing the polishing step. The polishing of the wafer W is started in a state in which the supplying of the first liquid onto the wafer W and the rotating of the wafer W are continued. The rotating of the wafer W and the supplying of the liquid are continued until the process (including the polishing step and the cleaning step) of the wafer W is terminated. Therefore, the centrifugal force continues to act on the liquid supplied onto the wafer W until the process of the wafer W is terminated, and the liquid can push the foreign matter out of the wafer W by the centrifugal force.

FIG. 9 is a view showing the polishing apparatus during the cleaning step. When the polishing step is performed for a predetermined time, the polishing head assembly 1A separates the polishing tape 23 from the wafer W to terminate the polishing step. As shown in FIG. 9, the polishing head 30 of the polishing head assembly 1B brings the cleaning tape 29 into contact with the wafer W to start the cleaning step. In one embodiment, the cleaning tape 29 is pressed to the same position as a polishing position of the wafer W by the polishing tape 23.

In this embodiment, the second-liquid upper supply step for supplying the second liquid is started at the same time as the first-liquid upper supply step is terminated, and the cleaning step is started at the same time as the second-liquid upper supply step is started. In one embodiment, the cleaning step may be started after the second-liquid upper supply step is started. In another embodiment, the cleaning step may be started before the second-liquid upper supply step is started. In this case, the cleaning step and the polishing step may be started at the same time.

In one embodiment, as indicated by the dotted arrow in FIG. 7, the polishing step by the polishing tape 23 may be continued for a predetermined time while the cleaning step by the cleaning tape 29 is started after the first-liquid upper supply step is terminated. The predetermined time is shorter than a performance time of the cleaning step.

In this embodiment, the second-liquid upper supply step is started at the same time as the first-liquid upper supply step is terminated. Therefore, the upper surface of the wafer W is continually kept wet by the first liquid and the second liquid. The second liquid is either of the conducting water, the surfactant solution, or ozone water (see FIG. 7).

The wafer W may be electrostatically charged during the polishing step. The foreign matter generated by polishing of the wafer W may adhere to the surface of the wafer W which is electrostatically charged. The conducting water such as a carbonated water can prevent the wafer W from being electrostatically charged by supplying the conducting water to the wafer W, i.e., the wafer W can be eliminated a static electricity. Therefore, the conducting water can prevent the adherence of the foreign matter to the wafer W due to the static electricity. The carbonated water supplied to the wafer W has a predetermined carbonate concentration range capable of efficiently preventing the static electricity. Therefore, the carbonated water is supplied onto the wafer W within the predetermined carbonate concentration range.

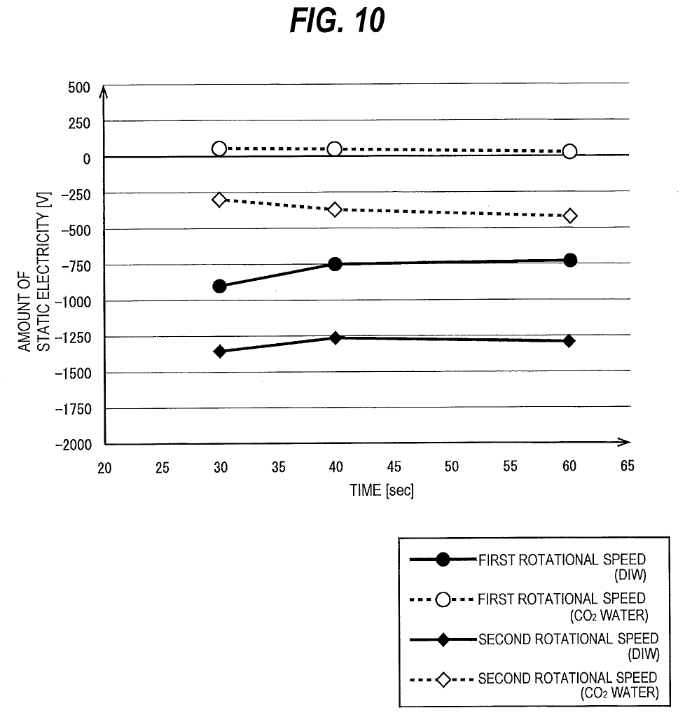

FIG. 10 is a view showing a temporal variation of an amount of static electricity of the wafer. In FIG. 10, a horizontal axis indicates a time [sec], and a vertical axis indicates the amount of static electricity [V]. Black circle symbols in FIG. 10 indicate the amount of static electricity when rotating the wafer at a first rotational speed while supplying pure water (DIW) onto the wafer. White circle symbols indicate the amount of static electricity when rotating the wafer at the first rotational speed while supplying the carbonated water (CO₂ water) onto the wafer.

Black rhombus symbols in FIG. 10 indicate the amount of static electricity when rotating the wafer at a second rotational speed higher than the first rotational speed while supplying pure water (DIW) onto the wafer. White rhombus symbols indicate the amount of static electricity when rotating the wafer at the second rotational speed while supplying the carbonated water (CO₂ water) onto the wafer. As is clear from FIG. 10, when the carbonated water is used as the liquid for supplying onto the wafer, the amount of static electricity of the wafer is suppressed compared to the amount of static electricity when pure water is used. Therefore, in order to suppress the static electricity of the wafer, the carbonated water is preferable used rather than pure water.

In one embodiment, as shown in FIG. 2, the polishing apparatus may include a ground wire 50 connected to the rotary joint 8. The ground wire 50 is grounded and can eliminate the static electricity from the wafer W through the holding stage 4 and the hollow shaft 5. By connecting the ground wire 50, the process required for processing the wafer W (more specifically, at least including the substrate rotating step, the first-liquid upper supply step, the polishing step, the second-liquid upper supply step, and the cleaning step) are performed in a state of eliminating the static electricity on the wafer W, i.e., in a state where the wafer W is eliminated the static electricity.

The surfactant solution can coat the surface of the wafer W by an action of the surfactant contained in the surfactant solution to prevent the adherence of the foreign matter to the surface of the wafer W. The surfactant solution has a predetermined concentration range for exhibiting a coating effect of the surfactant solution. Therefore, the surfactant solution is supplied to the wafer W within the predetermined concentration range.

Ozone water can make the surface of the wafer W hydrophilic by supplying ozone water onto the wafer W to remove the foreign matter from the surface of the wafer W. Ozone water has a predetermined concentration range for making the surface of the wafer W hydrophilic. Therefore, ozone water is supplied onto the wafer W in the predetermined concentration range.

In this manner, the upper liquid supply device 36 supplies the second liquid which can effectively prevent the adherence of the foreign matter to the wafer W onto the wafer W in the second-liquid upper supply step. The polishing head 30 presses the cleaning tape 29 against the wafer W while supplying the second liquid. Therefore, the polishing apparatus can reliably prevent the adherence of the foreign matter generated in the polishing step to the wafer W.

In this embodiment, the upper liquid supply device 36 supplies relatively inexpensive pure water in the first-liquid upper supply step. The upper liquid supply device 36 supplies the surfactant solution, the conducting water, or ozone water having a cleaning effect higher than that of the first liquid in the second-liquid upper supply step. Such a combination can reduce the cost required for processing the wafer W and reliably prevent the adherence of the foreign matter to the wafer W.

In one embodiment, the operation controller 69 may perform a step (second-liquid lower supply step) for supplying the liquid having the same type as the second liquid from the lower liquid supply devices 37, 38 onto the lower surface of the wafer W in the second-liquid upper supply step. As described above, the surfactant solution, the conducting water, and ozone water have an optimum concentration range for efficiently cleaning the wafer W, respectively. The type of the liquid supplied in the second-liquid lower supply step is the same as the type of the second liquid supplied in the second-liquid upper supply step. Therefore, the concentration of the second liquid is not diluted, and a nature of the second liquid does not change. Therefore, the second liquid can sufficiently exhibit effect of the second liquid.

As shown in FIG. 7, the operation controller 69 may perform a third-liquid upper supply step for supplying a third liquid which is either of pure water or the conducting water onto the upper surface of the wafer W after the second-liquid upper supply step is terminated. The third-liquid upper supply step is an upper rinse step for rinsing the wafer W.

In one embodiment, the third-liquid upper supply step may be performed when the second liquid supplied in the second-liquid upper supply step is the surfactant solution. With such a configuration, the third liquid can completely remove the surfactant solution remaining on the wafer W. In particular, when the third liquid is the conducting water, the third liquid can eliminate the static electricity from the wafer W while removing the surfactant solution. In another embodiment, when the second liquid is the conducting water, pure water may be used as the third liquid.

In FIG. 7, a time of the first-liquid upper supply step and a time of the second-liquid upper supply step are the same. A time of the third-liquid upper supply step is shorter than the time of the first-liquid upper supply step and the time of the second-liquid upper supply step. However, the times are not limited to this embodiment, and may be determined based on factors such as processing conditions of the wafer W.

In one embodiment, the operation controller 69 may perform a step (i.e., third-liquid lower supply step) for supplying the liquid of the same type as the third liquid from the lower liquid supply devices 37, 38 onto the lower surface of the wafer W. The third-liquid lower supply step is a lower rinse step for rinsing the wafer W.

When the process of the wafer W in the polishing apparatus is terminated, the operation controller 69 moves the polishing head assemblies 1A, 1B to a predetermined retract position and elevates the wafer W at a transfer position together with the holding stage 4 and the hollow shaft 5 by the air cylinder 15. The wafer W is separated from the holding stage 4 at the transfer position and carried out of the polishing room 21 by the transfer mechanism.

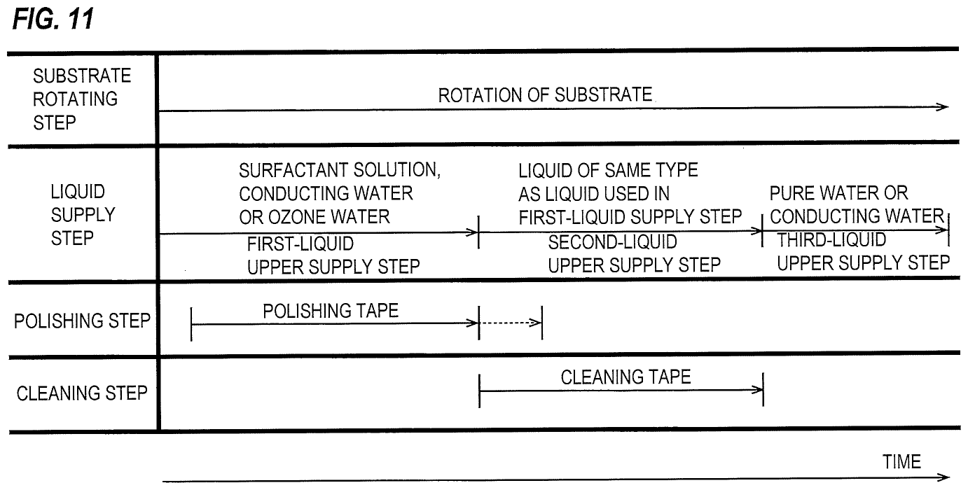

FIG. 11 is a view showing a sequence of the substrate processing method according to another embodiment. With reference to the construction and the operation of this embodiment which are the same as those of the embodiment reference to FIG. 7, a duplicate description thereof will be omitted.

In the embodiment shown in FIG. 11, the first liquid used in the first-liquid upper supply step is either of the surfactant solution, the conducting water, or ozone water. The second liquid used in the second-liquid upper supply step is a liquid of the same type as the first liquid. The third liquid used in the third-liquid upper supply step is pure water or the conducting water. Therefore, the same type of liquid is supplied onto the wafer W in the first-liquid upper supply step and the second-liquid upper supply step. In one embodiment, when the first liquid and the second liquid are ozone water, respectively the third liquid is preferably pure water.

When the surfactant solution is used as the first liquid, the foreign matter such as an unnecessary film formed on the bevel portion of the wafer W is removed by the polishing tape 23 in the presence of the first liquid. The combination of the surfactant solution and the polishing tape 23 can allow the first liquid to remove the foreign matter from the polishing tape 23, so that no foreign matter remains on the polishing tape 23. As a result, clogging of the polishing tape 23 is suppressed, and a polishing ability of the polishing tape 23 is maintained.

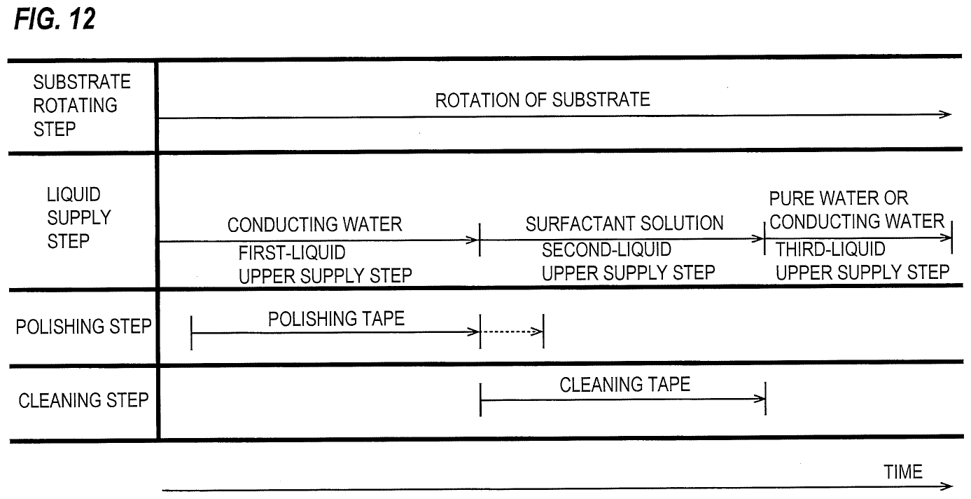

FIG. 12 is a view showing a sequence of the substrate processing method according to still another embodiment. With reference to the construction and the operation of this embodiment which are the same as those of the embodiment reference to FIGS. 7, 11, a duplicate description thereof will be omitted.

In the embodiment shown in FIG. 12, the first liquid used in the first-liquid upper supply step is the conducting water. The second liquid used in the second-liquid upper supply step is the surfactant solution. The third liquid used in the third-liquid upper supply step is pure water or the conducting water.

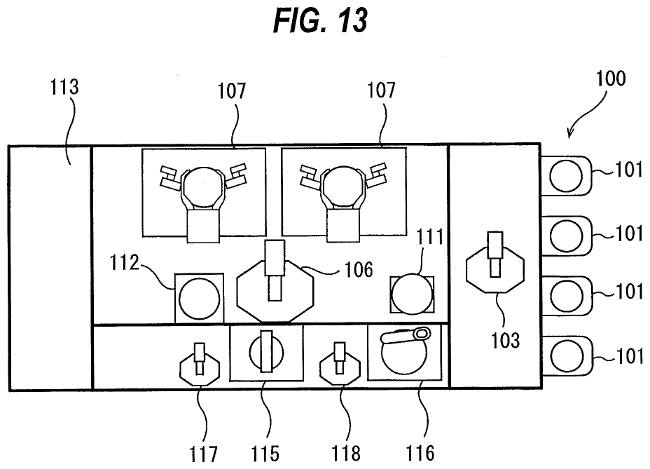

FIG. 13 is a plan view of a substrate processing apparatus including a plurality of polishing apparatuses described above. As shown in FIG. 13, the substrate processing apparatus has a loading and unloading section 100 including four front loaders 101 on which wafer cassettes, each storing a number of wafers therein, are placed. Each of the front loaders 101 is capable of receiving thereon an open cassette, an SMIF (Standard Manufacturing Interface) pod, or a FOUP (Front Opening Unified Pod). The SMIF and FOUP are a hermetically sealed container which houses a wafer cassette therein and covers it with a partition wall to thereby provide interior environments isolated from an external space.

The loading and unloading section 100 further includes a first transfer robot (loader) 103 movable along the array of the front loaders 101. The first transfer robot 103 can selectively access the wafer cassettes installed on the front loaders 101 and can remove the wafer from the wafer cassettes.

The substrate processing apparatus further includes a second transfer robot 106, a plurality of polishing apparatuses 107 arranged adjacent to the second transfer robot 106, a first wafer station 111 and a second wafer station 112 arranged on both sides of the second transfer robot 106, and an operation controller 113 configured to control overall operations of the substrate processing apparatus. The polishing apparatuses 107 correspond to the bevel polishing apparatus described in above-described embodiment, respectively. The operation controller 113 corresponds to the operation controller 69 described above.

The substrate processing apparatus further includes a cleaning unit 115 configured to clean the wafer processed by the polishing apparatus 107 and a drying unit 116 configured to dry the cleaned wafer. A third transfer robot 117 is arranged adjacent to the clean unit 115, and a fourth transfer robot 118 is arranged adjacent to the drying unit 116.

The operations of the substrate processing apparatus are as follows. The wafer is removed from the wafer cassette by the first transfer robot 103 and then placed on the first wafer station 111. The second transfer robot 106 holds the wafer on the first wafer station 111 and transfers the wafer into either one of the two polishing apparatuses 107.

The polishing apparatus 107 processes the bevel portion of the wafer according to the above-described operation sequence. The processed wafer is transferred from the polishing apparatus 107 to the second wafer station 112 by the second transfer robot 106. The wafer is further transferred from the second wafer station 112 to the cleaning unit 115 by the third transfer robot 117 and is cleaned by the cleaning unit 115. The cleaning in the cleaning unit 115 is a cleaning as a later process. Thereafter, the wafer is transferred from the cleaning unit 115 to the drying unit 116 by the fourth transfer robot 118 and is dried by the drying unit 116. After drying of the wafer, the wafer is carried to the wafer cassette by the first transfer robot 103 and is returned to an original position where the wafer has been stored.

In the above-described embodiment, the substrate processing method by the bevel polishing apparatus has been described, but this method is not limited to the bevel polishing apparatus. In embodiments described below, a substrate processing method by a back polishing apparatus configured to polish the back surface (i.e., surface on which no device is formed) of the wafer W will be described with reference to the drawings.

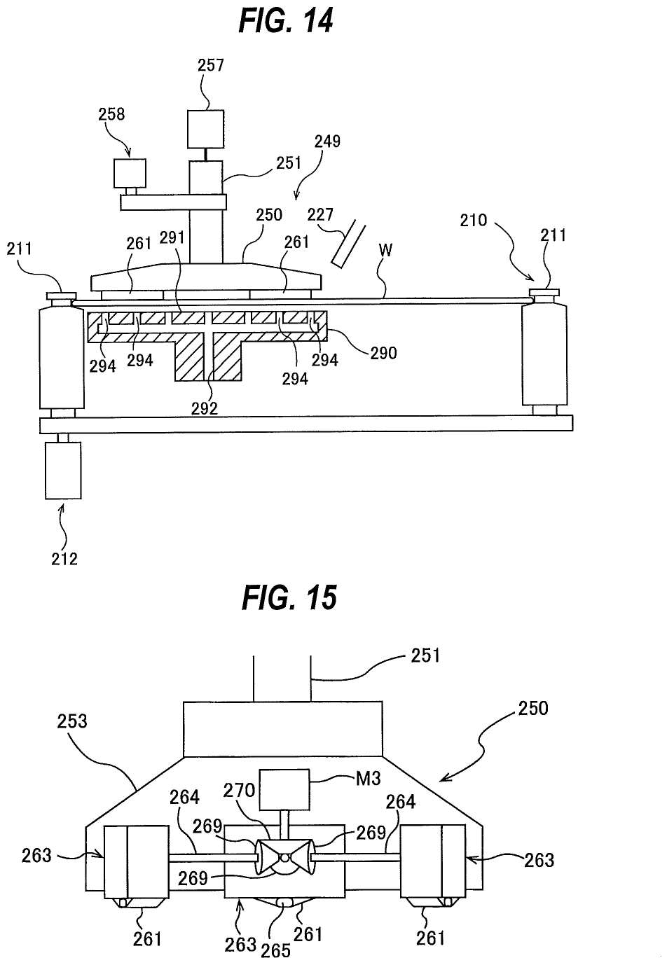

FIG. 14 is a schematic view showing another embodiment of the polishing apparatus. With reference to the construction and the operation of this embodiment which are the same as those of the above-described embodiment, a duplicate description thereof will be omitted.

The polishing apparatus includes a substrate holder 210 configured to hold the wafer W and rotate the wafer W about its axis, a processing head assembly 249 configured to process the upper surface of the wafer W held by the substrate holder 210 to remove the foreign matter from the upper surface of the wafer W, and a hydrostatic support stage 290 as a substrate support stage configured to support the lower surface of the wafer W opposite to the upper surface. The processing head assembly 249 is disposed above the wafer W held by the substrate holder 210. The hydrostatic support stage 290 is disposed below the wafer W held by the substrate holder 210.

In the embodiment, the upper surface of the wafer W is the back surface of the wafer W with no device is formed thereon, i.e., a non-device surface, while the opposite lower surface of the wafer W is a surface on which the device is formed, i.e., a device surface. A silicon surface is an example of the non-device surface. A surface on which a photoresist is coated is an example of the device surface. In this embodiment, the wafer W is held by the substrate holder 210 horizontally with the upper surface facing upward.

The substrate holder 210 includes a plurality of rollers 211 which can contact the peripheral portion of the wafer W, and a roller-rotating mechanism 212 configured to rotate the rollers 211 about their respective own axes. In this embodiment, four rollers 211 are provided. Five or more rollers 11 may be provided. In one embodiment, the roller-rotating mechanism 212 includes a motor, a belt, pulleys, etc. The roller-rotating mechanism 212 is configured to rotate the four rollers 211 at the same speed in the same direction. During the process of the upper surface of the wafer W, the peripheral portion of the wafer W is held by the rollers 211. The wafer W is held horizontally, and is rotated about its axis by the rotations of the rollers 211.

An upper liquid supply device 227 having the same configuration as the above-described upper liquid supply device 36 is disposed above the wafer W held by the substrate holder 210. Therefore, the detailed description of the upper liquid supply device 227 is omitted.

The processing head assembly 249 includes a processing head 250 configured to process the upper surface of the wafer W, held by the substrate holder 210, to remove the foreign matter, scratches, etc. from the upper surface of the wafer W. The processing head 250 is coupled to a head shaft 251. This head shaft 251 is coupled to a head-rotating mechanism 258 configured to rotate the processing head 250 about its axis. The head shaft 251 is further coupled to an air cylinder 257 as a load applying device configured to apply a downward load to the processing head 250. The processing head 250 includes a plurality of scrubbing tapes 261 as processing tools for processing the upper surface of the wafer W. The lower surface of the processing head 250 is a processing surface constituted by the scrubbing tapes 261. The processing head assembly 249 includes at least the processing head 250, the head shaft 251, the head-rotating mechanism 258, and the air cylinder 257.

The hydrostatic support stage 290 is one embodiment of a substrate support stage for supporting the lower surface of the wafer W held by the rollers 211. In this embodiment, the hydrostatic support stage 290 is configured to bring a fluid into contact with the lower surface of the wafer W, held by the rollers 211, so as to support the wafer W with the fluid. The hydrostatic support stage 290 has a substrate support surface 291 to be located close to the lower surface of the wafer W held by the rollers 211. Further, the hydrostatic support stage 290 includes a plurality of fluid ejection openings 294 formed in the substrate support surface 291, and a fluid supply passage 292 connected to the fluid ejection openings 294. The hydrostatic support stage 290 is disposed under the wafer W held by the substrate holder 210, with the substrate support surface 291 being spaced slightly apart from the lower surface of the wafer W. The fluid supply passage 292 is coupled to a not-shown fluid supply source.

The processing head 250 may preferably be disposed such that an edge of its lower surface lies on the center of the wafer W. The diameter of the lower surface of the processing head 250 may preferably be equal to or larger than the radius of the wafer W. In this embodiment, the diameter of the substrate support surface 291 is larger than the diameter of the lower surface of the processing head 250. In one embodiment, the diameter of the substrate support surface 291 may be equal to or smaller than the diameter of the lower surface of the processing head 250.

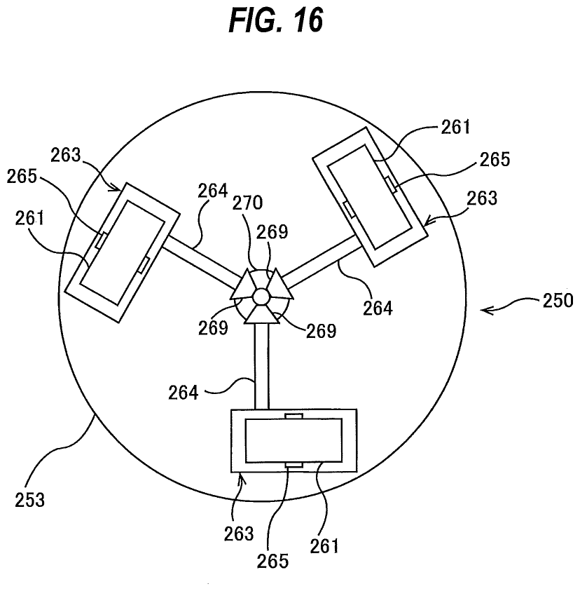

FIG. 15 is a view showing an example of an interior structure of the processing head 250. FIG. 16 is a view of the processing head 250 as seen from below. The processing head 250 includes a housing 253, a plurality of (three in FIG. 15) processing cartridges 263 arranged in the housing 253, a plurality of tape take-up shafts 264 coupled to the processing cartridges 263, respectively, and a motor M3 coupled to the tape take-up shafts 264. The processing cartridges 263 are removably installed inside the housing 253. In one embodiment, the processing head 250 may include four or more processing cartridges 263. One ends of the plurality of tape take-up shafts 264 are coupled to the processing cartridges 263, respectively, and a plurality of bevel gears 269 are fixed to the other ends of the tape take-up shafts 264, respectively. These bevel gears 269 mesh with a bevel gear 270 coupled to the motor M3.

The processing cartridges 263 include the plurality of scrubbing tapes 261, respectively. These scrubbing tapes 261 are arranged at equal intervals around the axis of the processing head 250. The processing head 250 brings the plurality of scrubbing tapes 261 into contact with the upper surface of the wafer W while rotating about the axis of the processing head 250 to thereby process the upper surface.

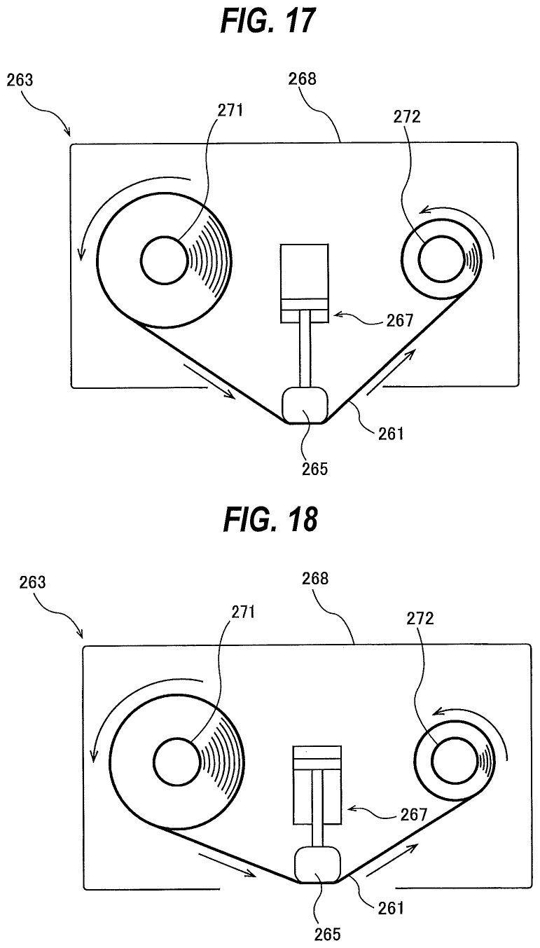

FIG. 17 is a schematic view showing one of the plurality of processing cartridges 263. As shown in FIG. 17, the processing cartridge 263 includes a pressing member 265 configured to press the scrubbing tape 261 against the upper surface of the wafer W, a position switching device 267 configured to be able to switch a position of the pressing member 265 between a processing position and a retreat position, and a cassette 268 accommodating the scrubbing tape 261, the pressing member 265, and the position switching device 267 therein. The position switching device 267 is an actuator for moving the pressing member 265 upwardly and downwardly. In this embodiment, an air cylinder is used as the position switching device 267. The above-described operation controller 69 (see FIG. 2) controls an operation of the position switching device 267.

Each of the processing cartridges 263 includes a tape feeding reel 271 configured to feed out the scrubbing tape 261 and a tape take-up reel 272 configured to take up the scrubbing tape 261 that has been used in processing of the wafer W. The tape feeding reel 271 and the tape take-up reel 272 are disposed in the cassette 268. The tape take-up reel 272 is coupled to one end of the tape take-up shaft 264 shown in FIGS. 15 and 17. Therefore, the tape take-up reel 272 can be driven by the motor M3 shown in FIG. 15 to take up the scrubbing tape 261.

The motor M3, the bevel gears 269, 270, and the tape take-up shaft 264 constitute a tape advancing mechanism for advancing the scrubbing tape 261 from the tape feeding reel 271 to the tape take-up reel 272. The scrubbing tape 261 is fed out from the tape feeding reel 271 in a direction of arrow in FIG. 17, passes on a lower surface of the pressing member 265, and is taken up by the tape take-up reel 272. The pressing member 265 presses the scrubbing tape 261 downward to bring the scrubbing tape 261 into contact with the upper surface of the wafer W to thereby process the upper surface.

FIG. 17 shows a state in which the pressing member 265 and the scrubbing tape 261 are located at the processing position. This processing position is a position at which the scrubbing tape 261 contacts the upper surface of the wafer W. FIG. 18 is a schematic view showing a state in which the pressing member 265 and the scrubbing tape 261 are located at the retreat position. This retreat position is a position at which the scrubbing tape 261 separates from the upper surface of the wafer W. The position switching device 267 can switch the position of the pressing member 265 and the scrubbing tape 261 between the processing position and the retreat position by moving the pressing member 265 between the processing position and the retreat position.

The position switching device 267 can maintain the pressing member 265 and the scrubbing tape 261 at the retreat position. Furthermore, the plurality of position switching devices 267 can operate independently of each other. Therefore, the plurality of position switching devices 267 can bring at least one of the scrubbing tapes 261 into contact with the upper surface of the wafer W, while keeping the other scrubbing tape 261 away from the upper surface of the wafer W.

The back surface polishing apparatus in the embodiment shown in FIGS. 14 to 18 can also perform the substrate processing method in the same manner as the polishing apparatus in the embodiment described above. The processing head 250 includes the processing cartridge 263 including the scrubbing tape 261 which corresponds to the polishing tape 23 described above, and the processing cartridge 263 including the scrubbing tape 261 which corresponds to the cleaning tape 29 described above. The scrubbing tape 261 corresponding to the polishing tape 23 may be referred to as a polishing tape 261. The scrubbing tape 261 corresponding to the cleaning tape 29 may be referred to as a cleaning tape 261.

With such a configuration, the operation controller 69 operates the position switching device 267 to switch the position of the pressing member 265 between the processing position and the retreat position. The operation controller 69 may bring the polishing tape 261 and/or the cleaning tape 261 into contact with the upper surface of the wafer W or may separate the polishing tape 261 and/or the cleaning tape 261 from the upper surface based on the sequence of the substrate processing method described in the embodiment in FIGS. 7, 11, and 12. Simply put, the operation controller 69 can press the polishing tape 261 to the upper surface of the wafer W in the polishing step and can press the cleaning tape 261 to the upper surface of the wafer W in the cleaning step. In this manner, the back polishing apparatus in the embodiment shown in FIGS. 14 to 18 can exhibit the same effect as the polishing apparatus (i.e., bevel polishing apparatus) in the above-described embodiment.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A method comprising:
a substrate rotating step of rotating a substrate while holding the substrate;
a first-liquid upper supply step of supplying a first liquid onto an upper surface of the substrate while rotating the substrate;
a polishing step of pressing a polishing tape to the substrate while supplying the first liquid in a state of rotating the substrate;
a second-liquid upper supply step of supplying a second liquid onto the upper surface of the substrate while rotating the substrate, the second liquid being either of a conducting water, a surfactant solution, or ozone water; and
a cleaning step of pressing a cleaning tape to the substrate while supplying the second liquid in a state of rotating the substrate and terminating after the polishing step is terminated.

2. The method according to claim 1, wherein the first liquid is either of pure water, a conducting water, a surfactant solution, or ozone water.

3. The method according to claim 1, further comprising:
a third-liquid upper supply step of supplying a third liquid being either of pure water or a conducting water onto the upper surface of the substrate while rotating the substrate after the second liquid upper supply step is terminated.

4. The method according to claim 1, wherein:
the polishing step comprises a pressing of the polishing tape to a peripheral portion of the substrate; and
the cleaning step comprises a pressing of the cleaning tape to the peripheral portion of the substrate.

5. The method according to claim 1, wherein:
the upper surface of the substrate is a back surface with no device is formed;
the polishing step comprises a pressing of the polishing tape to the back surface of the substrate; and
the cleaning step comprises a pressing of the cleaning tape to the back surface of the substrate.

6. The method according to claim 1, wherein:
the polishing tape is a tape having a first abrasive grain on a surface of the polishing tape; and
the cleaning tape is a tape having no abrasive grain on a surface of the cleaning tape or having a second abrasive grain.

7. The method according to claim 6, wherein:
the first abrasive grain is a diamond abrasive grain; and
the second abrasive grain is a silica abrasive grain.

8. The method according to claim 6, wherein a particle size of the second abrasive grain is smaller than a particle size of the first abrasive grain.

9. The method according to claim 1, wherein the substrate rotating step, the first-liquid upper supply step, the polishing step, the second-liquid upper supply step, and the cleaning step are performed in a state of eliminating a static electricity from the substrate.

10. The method according to claim 1, further comprising:
a first-liquid lower supply step of supplying a liquid of the same type as the first liquid onto a lower surface of the substrate in the first-liquid upper supply step; and
a second-liquid lower supply step of supplying a liquid of the same type as the second liquid onto the lower surface of the substrate in the second-liquid upper supply step.
